(19) United States
(12) Patent Application Publication
(10) Pub. No.: US 2023/0137506 A1
(43) Pub. Date: May 4, 2023

(54) PROCESSING SYSTEM FOR PROCESSING A FLEXIBLE SUBSTRATE AND METHOD OF MEASURING AT LEAST ONE OF A PROPERTY OF A FLEXIBLE SUBSTRATE AND A PROPERTY OF ONE OR MORE COATINGS ON THE FLEXIBLE SUBSTRATE

(71) Applicant: Applied Materials, Inc., Santa Clara, CA (US)

(72) Inventors: Thomas DEPPISCH, Aschaffenburg (DE); Ezhiylmurugan RANGASAMY, San Jose, CA (US); Stefan BANGERT, Steinau (DE); Mathew Dean ALLISON, Frankfurt (DE)

(21) Appl. No.: 17/442,415

(22) PCT Filed: Aug. 16, 2021
(86) PCT No.: PCT/US2021/046122

§ 371 Date: Sep. 23, 2021

Related U.S. Application Data
(60) Provisional application No. 63/068,826, filed on Aug. 21, 2020.

(51) Int. Cl. C23C 14/56; C23C 14/50; C23C 14/54; C23C 14/16

(52) U.S. Cl. CPC C23C 14/568; C23C 14/50; C23C 14/547; C23C 14/16

(57) ABSTRACT

A processing system for processing a flexible substrate is described. The processing system includes a vacuum chamber having a wall with an opening for the flexible substrate, a substrate support for supporting the flexible substrate during transportation of the flexible substrate through the opening, and a measurement assembly for measuring at least one of a property of the flexible substrate and a property of one or more coatings on the flexible substrate. The measurement assembly and the substrate support are attached to the wall.

### TECHNICAL FIELD

Embodiments of the present disclosure relate to processing system for processing a flexible substrate, particularly roll-to-roll processing system. In particular, embodiments of the present disclosure relate to vacuum processing systems having a measurement system for measuring a property of a flexible substrate and/or a property of one or more coatings provided on the flexible substrate. Further embodiments of the present disclosure relate to methods of measuring a property of a flexible substrate and/or a property of one or more coatings provided on the flexible substrate, particularly in situ.

### BACKGROUND

Processing of flexible substrates, such as plastic films or foils, is in high demand in the packaging industry, semiconductor industries and other industries. Processing may consist of coating a flexible substrate with a material, such as a metal, a semiconductor and a dielectric material, etching and other processing actions conducted on a substrate for the respective applications. Systems performing this task typically include a coating drum, e.g. a cylindrical roller, coupled to a processing system with a roller assembly for transporting the substrate, and on which at least a portion of the substrate is coated.

For example, a coating process such as a CVD process, a PVD process, or an evaporation process, can be utilized for depositing thin layers onto flexible substrates. Roll-to-roll deposition apparatuses are understood in that a flexible substrate of a considerable length, such as one kilometer or more, is uncoiled from a storage spool, coated with a stack of thin layers, and recoiled again on a wind-up spool. In particular, in the manufacture of thin film batteries, e.g. lithium batteries, the display industry and the photovoltaic (PV) industry, roll-to-roll deposition systems are of high interest. For example, the increasing demand for flexible touch panel elements, flexible displays, and flexible PV modules results in an increasing demand for depositing suitable layers in R2R-coaters.

There is a continuous demand for improved processing systems with which thin, uniform and high quality layers or layer stacks can be coated on flexible substrates. Improvements to the layers or layer stack systems being, for instance, having improved uniformity, improved product lifetime, and a lower number of defects per surface area, Accordingly, there is a demand for providing improved quality inspection methods as well as improved processing systems with processing quality inspection systems, e.g. for measuring coating thickness, which are capable of providing highly accurate measurement results.

### SUMMARY

In light of the above, a processing system for processing a flexible substrate, multiple drum roll-to-roll processing system for coating a flexible substrate, and a method of measuring at least one of a property of a flexible substrate and a property of one or more coatings on the flexible substrate according to the independent claims are provided. Further aspects, advantages, and features are apparent from the dependent claims, the description, and the accompanying drawings.

According to an aspect of the present disclosure, a processing system for processing a flexible substrate is provided. The processing system includes a vacuum chamber having a wall with an opening for the flexible substrate, Additionally, the processing system includes a substrate support for supporting the flexible substrate during transportation of the flexible substrate through the opening. Further, the processing system includes a measurement assembly for measuring at least one of a property of the flexible substrate and a property of one or more coatings on the flexible substrate. The measurement assembly and the substrate support are attached to the wall.

According to a further aspect of the present disclosure, a multiple drum roll-to-roll processing system for coating a flexible substrate on both sides is provided. The processing system includes a first vacuum deposition chamber having a first coating drum configured for guiding the flexible substrate past one or more first deposition units. Additionally, the processing system includes a second vacuum deposition chamber having a second coating drum configured for guiding the flexible substrate past one or more second deposition units. Further, the processing system includes a transportation system configured for transporting the flexible substrate such that a front side of the flexible substrate faces the one or more first deposition units and a backside of the flexible substrate faces the one or more second deposition units. Moreover, the processing system includes first thickness measurement assembly, a second thickness measurement assembly, and a third thickness measurement assembly. The first thickness measurement assembly is attached to a wall of the first vacuum deposition chamber having a first opening for the flexible substrate. The second thickness measurement assembly is attached to a wall of the first vacuum deposition chamber having a second opening for the flexible substrate. The third thickness measurement assembly is attached to a wall of the second vacuum deposition chamber having an third opening for the flexible substrate.

According to another aspect of the present disclosure, a method of measuring at least one of a property of a flexible substrate and a property of one or more coatings on the flexible substrate is provided. The method includes supporting the flexible substrate by a substrate support during transportation of the flexible substrate through an opening provided in a wall of a vacuum chamber. The substrate support is attached to the wall. Further, the method includes measuring at least one of a property of the flexible substrate and a property of one or more coatings on the flexible substrate by using a measurement assembly attached to the wall.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of a processing system according to embodiments described herein;

FIG. 2 shows a schematic view of a measurement assembly of a processing system according to embodiments described herein;

FIG. 3 shows a schematic front view of a measurement assembly of a processing system according to further embodiments described herein;

FIG. 4 shows a schematic view of a processing system having a coating drum and one or more deposition units according to further embodiments described herein;

FIG. 5 shows a schematic view of a multiple drum roll-to-roll processing system for coating a flexible substrate on both sides according to embodiments described herein; and

FIG. 6 shows a block diagram for illustrating a method of measuring at least one of a property of a flexible substrate and a property of one or more coatings on the flexible substrate according to embodiments described

### DETAILED DESCRIPTION OF EMBODIMENTS

Reference will now be made in detail to the various embodiments of the disclosure, one or more examples of which are illustrated in the figures. Within the following description of the drawings, same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

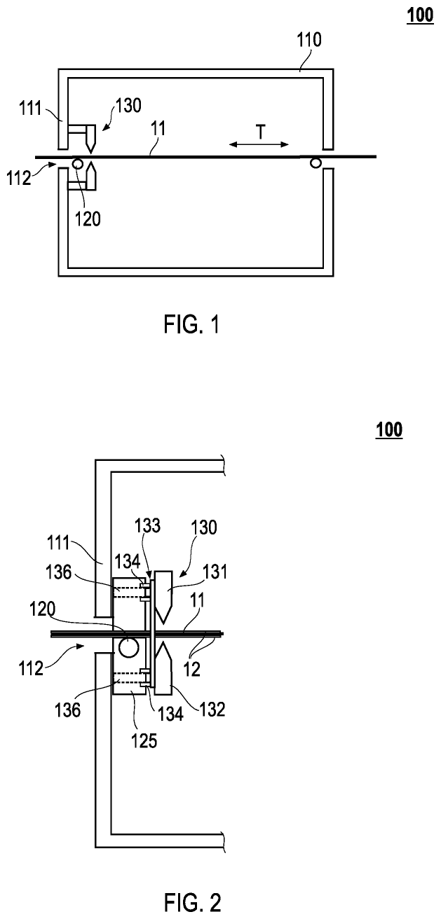

With exemplary reference to FIG. 1, a processing system 100 for processing a flexible substrate 11 according to the present disclosure is described.

According to embodiments, which can be combined with any other embodiments describe herein, the processing system 100 includes a vacuum chamber 110 having a wall 111 with an opening 112 for the flexible substrate 11. Additionally, as exemplarily shown in FIG. 1, the processing system 100 includes a substrate support 120 for supporting the flexible substrate 11 during transportation of the flexible substrate 11 through the opening 112. Further, the processing system 100 includes a measurement assembly 130 for measuring a property of the flexible substrate 11 and/or a property of one or more coatings on the flexible substrate 11. FIG. 2 shows the substrate with coatings 12 on the flexible substrate 11, particularly a first coating on the front side of the flexible substrate and a second coating on the backside of the flexible substrate. As exemplarily shown in FIG. 1, the measurement assembly 130 and the substrate support 120 are attached to the wall 111.

Accordingly, compared to the state of the art, the processing system as described herein beneficially provides for improved quality inspection of unprocessed and processed flexible substrates. In particular, by providing a measurement assembly and a substrate support both attached to the wall of the vacuum chamber negative influences on the measurement results can be reduced or even avoided. In particular, negative influences due to substrate tension, vacuum and/or thermal effects can be reduced or even eliminated. In other words, embodiments as described herein are beneficially configured such that the relative position of the measure assembly with respect to the unprocessed or processed substrate to be measured is substantially constant, i.e. the distance between the measure assembly and the unprocessed or processed substrate to be measured is not or only negligibly affected by vacuum deformation of the vacuum chamber and/or thermal deformation effects.

Before various further embodiments of the present disclosure are described in more detail, some aspects with respect to some terms used herein are explained.

In the present disclosure, a “processing system for processing a flexible substrate” can be understood as a system configured for continuously processing a flexible substrate. In particular, the processing system is a roll-to-toll processing system configured for depositing material on the flexible substrate. More specifically, the processing system can be a vacuum processing system having at least one vacuum chamber, particularly a vacuum deposition chamber. For instance, the processing system may be configured for a substrate length of 500 m or more, 1000 m or more, or several kilometers. The substrate width can be 300 mm or more, particularly 500 mm or more, more particularly 1 m or more, Further, the substrate width can be 3 m or less, particularly 2 m or less.

In the present disclosure, a “flexible substrate” can be understood as a bendable substrate. The term “flexible substrate” or “substrate” may be synonymously used with the term “foil” or the term “web”. In particular, it is to be understood that embodiments of the processing system described herein can be utilized for processing any kind of flexible substrate, e.g. for manufacturing flat coatings with a uniform thickness, For example, a flexible substrate as described herein may include materials like PET, HC-PET, PE, PI, PU, TaC, OPP, CPP, one or more metals (e.g. copper or aluminium), paper, combinations thereof, and already coated substrates like Hard Coated PET (e.g. HC-PET, HC-TaC) or metal coated polymeric substrates (e.g. copper coated PET) and the like. In particular, the substrate may be a metal foil, e.g. a foil consisting of copper. For example, the substrate thickness can be 2 μm. or more and 1 mm or less. Typically, the substrate is a non-transparent substrate.

In the present disclosure, a “vacuum chamber” can be understood as chamber configured to provide a vacuum within the chamber. Typically, the flexible substrate is transported through a vacuum chamber as described herein. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar.

In the present disclosure, an “opening for the flexible substrate” can be understood as an opening having dimensions such that flexible substrate can be transported through the opening. Accordingly, the opening for the flexible substrate may have an opening width of at least the width of the flexible substrate. Further, the opening for the flexible substrate may have an opening height of at least the thickness of the flexible substrate. Typically, opening width is larger than the width of the flexible substrate and the opening height is larger than the thickness of the flexible substrate. As described herein, the opening for the flexible substrate is provided in a wall of a vacuum chamber. Depending on the transport direction of the flexible substrate, the opening for the flexible substrate may be referred to as entrance opening or exit opening.

In the present disclosure, a “substrate support for supporting the flexible substrate” can be a roller. A “roller” may be understood as a device which provides a surface with which the flexible substrate or part of the flexible substrate may come in contact during transport of the flexible substrate. Typically, the substrate support includes a circular shape for contacting the flexible substrate during substrate transportation. The cylindrical shape is formed about a straight longitudinal axis of the substrate support, e.g. the roller. Accordingly, typically, the substrate support is configured for guiding the substrate while the substrate is transported. In particular, the substrate support can be part of a sealing device configured for vacuum sealing the opening in the wall of the vacuum chamber though which the substrate is transported into and out of the vacuum chamber.

In the present disclosure, a “measurement assembly for measuring at least one of a property of the flexible substrate and a property of one or more coatings on the flexible substrate” can be understood as an assembly configured for measuring one or more properties of the flexible substrate and/or one or more layers or coatings provided on the flexible substrate. For instance, the measurements assembly can be configured to measure at least one of a substrate thickness, a layer thickness, and a layer thickness uniformity. Typically, the measurement assembly includes one or more measurement devices, particularly optical measurement devices. In particular, the one or more measurement devices can be configured for measuring thickness via at least one of optical reflection, transmission, and optical interference. For example, the one or more measurement devices may be interferometers, particularly laser interferometers.

FIG. 2 shows a schematic exemplary embodiment of a measurement assembly of a processing system according to embodiments described herein. According to embodiments, which can be combined with any other embodiments describe herein, the substrate support 120 is part of a sealing device 125 for sealing the opening 112. In particular, the sealing device 125 is a gap sluice. As exemplary shown in FIG. 2, typically the sealing device 125 is disposed at or in the opening 112 for the flexible substrate 11. In particular, the sealing device 125 is tightly fixed to the wall 111, e.g. by screws or bolts. The sealing device may also be referred to as load lock or load lock valve.

As described herein, the substrate support 120 can be a roller configured for guiding the substrate during substrate transportation. For instance, the substrate support 120 may include a rigid cylindrical tube or rigid cylindrical bar disposed within an elastic tube. The elastic tube can be inflatable such that a portion of the elastic tube can be pressed against the flexible substrate to provide a vacuum sealing during substrate transportation. It is to be understood, that other sealing devices of different configuration may be implemented. Further, it is to be understood that any sealing device configured for vacuum sealing an opening through which a flexible substrate is transported has a substrate support 120, i.e. a part of the sealing device being in contact with the flexible substrate when the opening is sealed, Moreover, it is to be understood that a sealing device as described herein is configured for providing a vacuum sealing during substrate transportation.

With exemplary reference to FIG. 2, according to embodiments, which can be combined with any other embodiments describe herein, the measurement assembly 130 includes a measurement device holder 133 holding two or more measurement devices. The measurement device holder 133 is attached to the wall 111 by fastening elements 136, e.g. screws or bolts, In particular, the measurement assembly 130 may be attached to the wall 111 via the sealing device 125. As exemplarily shown in FIG. 2, the fastening elements 136 may extend into the sealing device 125. Additionally or alternatively, the fastening elements 136 may extend through the sealing device 125 and be fixed to the wall 111.

According to embodiments, which can be combined with any other embodiments describe herein, one or more spacers 134 are provided for providing a gap between the sealing device 125 and the measurement device holder 133, as exemplarily shown in FIG. 2. Accordingly, the measurement device holder 133 can be arranged at a distance from the sealing device, which is beneficial for minimizing or avoiding influence of load lock forces on the measurement device holder 133. In other words, deformation of the measurement device holder 133 due to load lock forces can be reduced or even eliminated.

According to embodiments, which can be combined with any other embodiments describe herein, the measurement device holder 133 is made of a material having a coefficient of thermal expansion α of α≤4×10⁻⁶ K⁻¹. In particular, the material of the measurement device holder 133 is a nickel-iron alloy, for example Invar. Providing the measurement device holder 133 made of a material as described herein is beneficial for reducing or even avoiding thermal deformation of the measurement device holder 133

According to embodiments, which can be combined with any other embodiments describe herein, the measurement assembly 130 includes a first measurement device 131 for measuring a front side 11A of the flexible substrate 11 and an opposite second measurement device 132 for measuring a backside 11B of the flexible substrate 11. Providing oppositely arranged measurement devices is beneficial for compensating winding related shifts of substrate position, such that the measurement quality and accuracy is improved. Typically, the first measurement device 131 and/or the second measurement device 132 are interferometers, particularly laser interferometers.

According to embodiments, which can be combined with any other embodiments described herein, the measurement assembly is configured for measuring a coating thickness on the flexible substrate. In particular, the measurement assembly is configured for measuring a thickness of a top coating and a thickness of a back coating on the flexible substrate. In other words, measurement assembly is configured for measuring a double side coating on the flexible substrate.

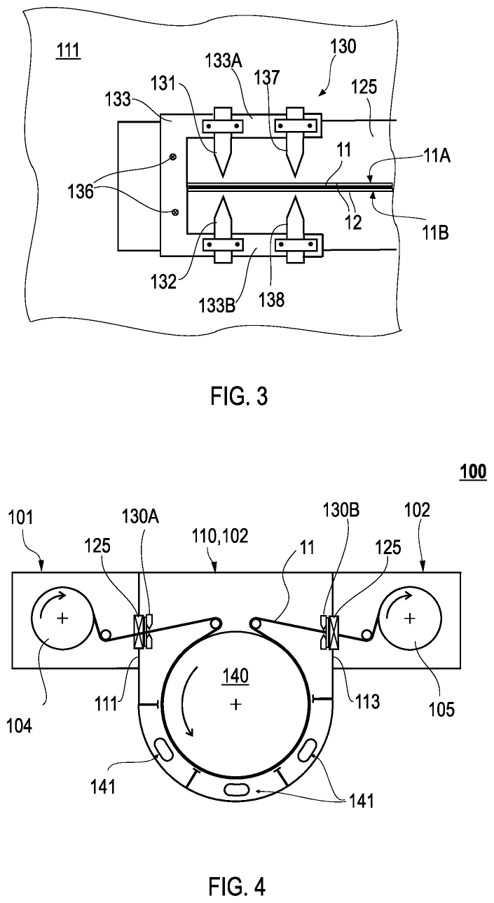

FIG. 3 shows a schematic front view of an exemplary measurement assembly of a processing system according to embodiments described herein. As exemplarily shown in FIG. 3, the measurement device holder 133 can have a C-shape configuration, e.g. having a first arm 133A and a second arm 133B. The first arm 133A and the second arm 133B are oppositely arranged. The first measurement device 131 may be mounted to the first arm 133A and the second measurement device 132 may be mounted to the second arm 133B. As exemplarily shown in FIG. 3, the measurement assembly 130 may further include a third measurement device 137 and a fourth measurement device 138. Typically, the third measurement device 137 is arranged and configured for measuring the front side 11A of the flexible substrate 11 and the fourth measurement device 138 is arranged and configured for measuring the backside 11B of the flexible substrate 11. The third measurement device 137 may be mounted to the first arm 133A, particularly next to the first measurement device 131. The fourth measurement device 138 may be mounted to the second arm 133B, particularly next to the second measurement device 132. Typically, the third measurement device 137 and/or the fourth measurement device 138 are interferometers, particularly laser interferometers.

Interferometers, particularly laser interferometers, have the advantage that very accurate thickness measurements can be carried out. In particular with interferometers, e.g. laser interferometers, distances can be measured with a resolution in the nanometer range. For example, the thickness of the substrate between two oppositely arranged measurement devices, particularly laser interferometers, can be determined by measuring the distance from top to the substrate and from bottom to the substrate. According to embodiments which can be combined with other embodiments described herein, first the uncoated substrate is measured, then the substrate with a first coating on a first side of the substrate, e.g. the a front side 11A, is measured, and after that the substrate with both sides coated, i.e. the first coating on the first side of the substrate and a second coating on a second side of the substrate, particularly the backside 11B, are measured. Accordingly, information about substrate thickness as well as about the thickness of the first coating and the second coating can be obtained.

With exemplary reference to FIG. 4, according to embodiments, which can be combined with any other embodiments describe herein, the processing system 100 is a roll-to-roll processing system having a coating drum 140 configured for guiding the flexible substrate 11 past one or more deposition units 141. According to embodiments, which can be combined with any other embodiments describe herein, at least one of the one or more deposition units 141 is configured for providing a lithium coating on the flexible substrate 11.

In the present disclosure, a “coating drum” can be understood as a drum or a roller having a substrate support surface for contacting the flexible substrate. In particular, the coating drum can be rotatable about a rotation axis and may include a substrate guiding region. Typically, the substrate guiding region is a curved substrate support surface, e.g. a cylindrically symmetric surface, of the coating drum. The curved substrate support surface of the coating drum may be adapted to be (at least partly) in contact with the flexible substrate during operation of the processing system.

In the present disclosure, a “deposition unit” can be understood as a unit or device configured for depositing material on a substrate. For example, the deposition unit may be a sputter deposition unit, a CVD deposition unit, an evaporation deposition unit, a PVD or PECVD deposition unit, or another suitable deposition unit.

As exemplarily shown in FIG. 4, according to embodiments, which can be combined with any other embodiments describe herein, the measurement assembly 130 includes a first measurement assembly 130A and a one or more further measurement assemblies 130B. Typically, the first measurement assembly 130A is arranged upstream from the coating drum 140. Accordingly, the first measurement assembly 130A can be used for measuring the unprocessed substrate. The one or more further measurement assemblies 130B are arranged downstream from the coating drum 140. Accordingly, the one or more further measurement assemblies 130B can be used for measuring the processed substrate, e.g. for measuring the thickness of one or more coatings provided on the front side 11A of the flexible substrate 11 and/or for measuring the thickness of one or more coatings provided on the backside 11B of the flexible substrate 11.

The terms “upstream from” and “downstream from” as used herein may refer to the position of the respective chamber or of the respective component with respect to another chamber or component along the substrate transportation path. For instance, as exemplarily shown in FIG. 4, during operation, the flexible substrate 11 is guided from the first spool chamber 101 through the processing chamber 102 and subsequently guided to the second spool chamber 103 along the substrate transportation path via a substrate transportation systems including a roller assembly. Accordingly, the processing chamber 102 is arranged downstream from the first spool chamber 101, and the first spool chamber 101 is arranged upstream from the processing chamber 102. When, during operation, the substrate is first guided by or transported past a first roller or a first component and subsequently guided by or transported past a second roller or a second component, the second roller or second component is arranged downstream from the first roller or first component.

According to embodiments, which can be combined with any other embodiments described herein, the one or more further measurement assemblies 135 are attached to a further wall 113 opposite the wall 111, as exemplarily shown in FIG. 4. The further wall 113 has a further opening 114 for the flexible substrate 11. As exemplarily shown in FIG. 4, typically a further substrate support 121 for supporting the flexible substrate 11 during transportation of the flexible substrate 11 through the further opening 114 is attached to the further wall 113. As exemplarily shown in FIG. 4, typically the wall 111 is a wall provided between the first spool chamber 101 and the processing chamber 102. The further wall 113 can be a wall between the processing chamber 102 and the second spool chamber 103. As exemplarily shown in FIG. 4, the first spool chamber 101 typically houses a storage spool 104 for providing the flexible substrate 10. The second spool chamber 103 typically houses a wind-up spool 105 for winding the flexible substrate 10 thereon after processing.

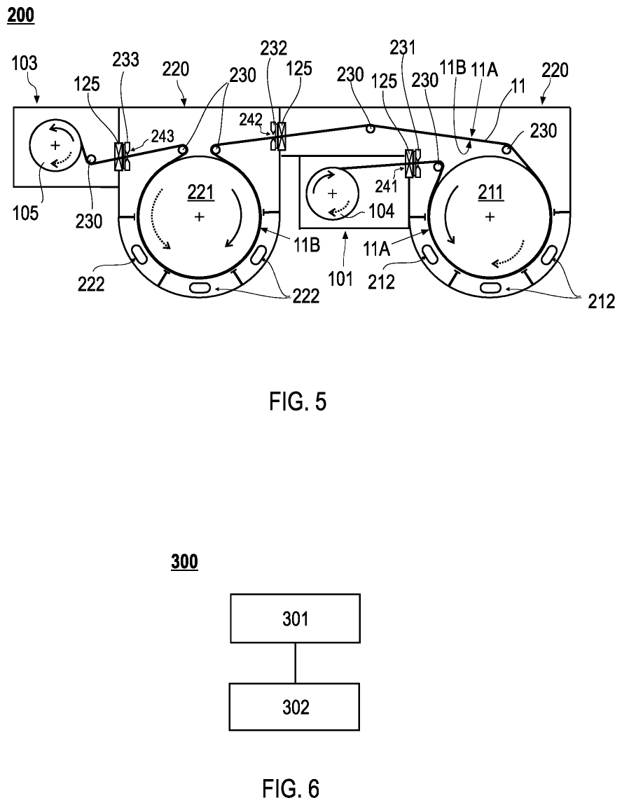

With exemplarily reference to FIG. 5, a multiple drum roll-to-roll processing system 200 for coating a flexible substrate 11 on both sides according to the present disclosure is described. According to embodiments, which can be combined with any other embodiments describe herein, the processing system includes a first vacuum deposition chamber 210 having a first coating drum 211 configured for guiding the flexible substrate 11 past one or more first deposition units 212. Additionally, the processing system S includes a second vacuum deposition chamber 220 having a second coating drum 221 configured for guiding the flexible substrate 11 past one or more second deposition units 222. Further, as exemplarily shown in FIG. 5, the processing system includes a transportation system 230 for transporting the flexible substrate 11 through the processing system. Typically, the transportation system 230 includes a roller assembly configured for guiding the flexible substrate. As exemplarily shown in FIG. 5, the transportation system 230 is configured for transporting the flexible substrate 11 such that a front side 11A of the flexible substrate faces the one or more first deposition units and a backside 11B of the flexible substrate faces the one or more second deposition units 222. Accordingly, a double sided coating can be provided on the flexible substrate. It is to be understood, that according to embodiments, which can be combined with any other embodiments describe herein, the flexible substrate can be moved back and forth. In other words, in a first run the flexible substrate can be moved in a first direction, e.g. as exemplarily indicated by the arrows in FIG. 5. In a second run the flexible substrate can be moved in a second direction opposite the first direction. The second direction is indicated by the dotted arrows in FIG. 5.

Moreover, as exemplarily shown in FIG. 5, the processing system includes a first thickness measurement assembly 231, a second thickness measurement assembly 232, and a third thickness measurement assembly 233. The first thickness measurement assembly 231 is attached to a wall of the first vacuum deposition chamber having a first opening 241 for the flexible substrate. The second thickness measurement assembly 23 is attached to a wall of the second vacuum deposition chamber 220 having a second opening 242 for the flexible substrate. The third thickness measurement assembly 233 is attached to a wall of the second vacuum deposition chamber having an third opening 243 for the flexible substrate. For instance, the first opening 241 can be an entrance opening for the flexible substrate into the first vacuum deposition chamber 210. The second opening 242 can be an entrance opening for the flexible substrate into the second vacuum deposition chamber 220. The third opening 243 can be an exit opening for the flexible substrate out of the second processing chamber, e.g. into the second spool chamber 103 including the wind-up spool 105. The first thickness measurement assembly 231 and/or the second thickness measurement assembly 232 and/or the third thickness measurement assembly 233 can be configured according to the measurement assembly 130 as exemplarily described with reference to FIGS. 1 to 4.

With exemplarily reference to the block diagram of FIG. 6, a method 300 of measuring at least one of a property of a flexible substrate 11 and a property of one or more coatings 12 on the flexible substrate according to the present disclosure is described. According to embodiments, which can be combined with any other embodiments describe herein, the method 300 includes supporting (represented by block 301 in FIG. 6) the flexible substrate 11 by a substrate support 120) during transportation of the flexible substrate 11 through an opening 112 provided in a wall 111 of a vacuum chamber 110. The substrate support 120 is attached to the wall 111. Further, the method includes measuring (represented by block 302 in FIG. 6) at least one of a property of the flexible substrate 11 and a property of one or more coatings 12 on the flexible substrate 11 by using a measurement assembly 130 attached to the wall 111.

Accordingly, compared to the state of the art, an improved quality inspection method for unprocessed and processed flexible substrates. In particular, by using a measurement assembly and a substrate support both attached to the wall of the vacuum chamber negative influences on the measurement results can be reduced or even avoided. In particular, negative influences due to substrate tension, vacuum and/or thermal effects can be reduced or even eliminated.

According to embodiments, which can be combined with any other embodiments describe herein, at least one of the one or more coatings measured by the method as described herein is a lithium coating. Further, typically the at least one of the property measured by the measurement assembly employed in the method is a thickness.

According to embodiments, which can be combined with any other embodiments describe herein, the flexible substrate is selected form the group consisting of a polymeric substrate, particularly a PET substrate, a metallic substrate, particularly a copper substrate, and polymeric substrate with a metallic coating, particularly a PET substrate with a copper coating.

In view of the above, it is to be understood that compared to the state of the art, embodiments of the present disclosure beneficially provide processing systems and methods which are which are capable of providing highly accurate measurement results, particularly due to the fact that negative influences caused by substrate tension, vacuum and/or thermal effects are reduced or even eliminated.

While the foregoing is directed to embodiments, other and further embodiments may be devised without departing from the basic scope, and the scope is determined by the claims that follow.

1. A processing system for processing a flexible substrate, comprising
a vacuum chamber having a wall with an opening for the flexible substrate;
a substrate support for supporting the flexible substrate during transportation of the flexible substrate through the opening; and
a measurement assembly for measuring at least one of a property of the flexible substrate and a property of one or more coatings on the flexible substrate, the measurement assembly and the substrate support being attached to the wall.

2. The processing system for processing a flexible substrate of claim 1, the substrate support being part of a sealing device, for sealing the opening.

3. The processing system for processing a flexible substrate of claim 1, the measurement assembly comprising a measurement device holder holding two or more measurement devices, the measurement device holder being attached to the wall.

4. The processing system for processing a flexible substrate of claim 3, further comprising one or more spacers providing a gap between the sealing device and the measurement device holder.

5. The processing system for processing a flexible substrate of claim 3. the measurement device holder being made of a material having a coefficient of thermal expansion α of α≤4×10 ⁻⁶ K⁻¹.

6. The processing system for processing a flexible substrate of claim 1, the measurement assembly comprising a first measurement device for measuring a front side of the flexible substrate and an opposite second measurement device for measuring a backside of the flexible substrate.

7. The processing system for processing a flexible substrate of claim 2, the measurement assembly being attached to the wall via the sealing device.

8. The processing system for processing a flexible substrate of claim 1, the measurement assembly being configured for measuring a coating thickness on the flexible substrate.

9. The processing system for processing a flexible substrate of claim 1, the substrate processing system being a roll-to-roll processing system having a coating drum configured for guiding the flexible substrate past one or more deposition units.

10. The processing system for processing a flexible substrate of claim 9, wherein at least one of the one or more deposition units are configured for providing a lithium coating on the flexible substrate.

11. The processing system for processing a flexible substrate of claim 9, the measurement assembly comprising a first measurement assembly being arranged upstream from the coating drum, and the substrate processing system further comprising one or more further measurement assemblies being arranged downstream from the coating drum.

12. The processing system for processing a flexible substrate of claim 11, the one or more further measurement assemblies being attached to a further wall opposite the wall, the further wall having a further opening for the flexible substrate, and wherein a further substrate support for supporting the flexible substrate during transportation of the flexible substrate through the further opening is attached to the further wall.

13. A multiple drum roll-to-roll processing system for coating a flexible substrate on both sides, comprising
a first vacuum deposition chamber having a first coating drum configured for guiding the flexible substrate past one or more first deposition units,
a second vacuum deposition chamber having a second coating drum configured for guiding the flexible substrate past one or more second deposition units,
a transportation system configured for transporting the flexible substrate such that a front side of the flexible substrate faces the one or more first deposition units and a backside of the flexible substrate faces the one or more second deposition units,
a first thickness measurement assembly attached to a wall of the first vacuum deposition chamber having a first opening for the flexible substrate;
a second thickness measurement assembly attached to a wall of the second vacuum deposition chamber having a second opening for the flexible substrate; and
a third thickness measurement assembly attached to a wall of the second vacuum deposition chamber having a third opening for the flexible substrate.

14. A method of measuring at least one of a property of a flexible substrate and a property of one or more coatings on the flexible substrate, the method comprising
supporting the flexible substrate by a substrate support during transportation of the flexible substrate through an opening provided in a wall of a vacuum chamber, the substrate support being attached to the wall, and
measuring at least one of a property of the flexible substrate and a property of one or more coatings on the flexible substrate by using a measurement assembly attached to the wall.

15. The method of measuring at least one of a property of a flexible substrate and a property of one or more coatings on the flexible substrate of claim 14, wherein at least one of the one or more coatings is a lithium coating, and the at least one of a property is a thickness.

16. The method of measuring at least one of a property of a flexible substrate and a property of one or more coatings on the flexible substrate of claim 14, wherein the flexible substrate is selected from the group consisting of a polymeric substrate, a metallic substrate, and polymeric substrate with a metallic coating.

17. The processing system for processing a flexible substrate of claim 1, wherein substrate support is part of a gap sluice.

18. The processing system for processing a flexible substrate of claim 5, wherein the material is selected from a nickel-iron alloy and Invar.

19. The processing system for processing a flexible substrate of claim 6, wherein the first measurement device and the second measurement device are laser interferometers.

20. The processing system for processing a flexible substrate of claim 8, wherein the measurement assembly is configured for measuring a thickness of a top coating and a thickness of a back coating on the flexible substrate.
